(19) United States
(12) Patent Application Publication
(10) Pub. No.: US 2006/0202341 A1
(43) Pub. Date: Sep. 14, 2006

(54) Semiconductor device, and method of manufacturing the same

(75) Inventor: Shinya Ito, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/369,950

(22) Filed: Mar. 8, 2006

(30) Foreign Application Priority Data
Mar. 10, 2005 (JP) 2005-066719

(51) Int. Cl. H01L 23/52

(52) U.S. Cl. 257/758

(57) ABSTRACT

A defective opening caused by the shortage of light amounts at performing exposure for forming a contact or a via is controlled. The cross-sectional shape of the contact plug 17 includes a plurality of first regions 302 arranged at a predetermined distance in the longitudinal direction, and a second region 304 which has a width narrower than that of the first region, and joins the first regions 302 which are adjacent to each other. Each of the first regions 302 has a circular-arc shape (at least a part of the outside edge of the region has the circular-arc shape). A ratio b/a=(d−r)/r between the longitudinal length of the second region 304 and that of the first region 302 is set equal to or less than 0.5.

This application is based on Japanese Patent application NO.2005-066719, the content of which is incorporated hereinto by reference.

### BACKGROUND

1. Technical Field

The present invention relates to a semiconductor device provided with a conductive plug.

2. Related Art

A structure using a so-called common contact has been known as a local interconnection structure which electrically connects the gate electrode and the source-drain region of a Metal-Oxide-Semiconductor (MOS) type field-effect transistor (hereinafter, referred as MOS transistor). FIG. 7 is a view showing one example of a local interconnection structure using a common contact.

A MOS transistor Tr is covered with an insulating interlayer formed on the surface of a substrate 110. A contact hole 118, which vertically penetrates through the insulating interlayer 116, is formed in the insulating interlayer 116. The above contact hole 118 is in contact with both the gate electrode 114 and the source-drain region 112a. Thereby, the gate electrode 114 and the source-drain region 112a are electrically connected to each other.

An interconnection (not shown) is formed on the insulating interlayer 116 in such a way that the interconnection comes into contact with the upper end of a contact plug 117. Thereby, common connection between the gate electrode 114 and the source-drain region 112a is electrically made through one contact plug 117 according to the above interconnection. That is, the gate electrode 114 and the source-drain region 112a are connected to each other through the contact hole 118 and the contact plug 117, which are common to the electrode 114 and the region 112a.

FIG. 8A is a view showing one example of a mask M101 for making a pattern on a photoresist film, wherein the film is used during a process in which the contact hole 118 is formed in the insulating interlayer 116. A rectangular window w101, which is formed in such a way that the window 101 stretches over the gate electrode 114 and the source-drain region 112a, is provided on the mask M101 at a position corresponding to the contact hole 118. The contact hole 118 which is actually formed in the insulating interlayer 116 with the window w101 in the above mask M101 has an almost-elliptic shape as a plan view as shown in FIG. 8B.

However, in the local interconnection structure using the “common contact” shown in FIG. 7, a leakage current is sometimes caused in a location just under a side wall spacer 115 at the side of the source-drain region 112a as shown in FIG. 7 by the arrow A. The reason will be described as explained hereafter.

Since the side wall spacer 115 is formed by etch back of the insulating interlayer, the outside surface of the side wall spacer 115 is not perpendicular, but somewhat inclined to the surface of the substrate 110 as shown in FIG. 7. Moreover, the insulating interlayer 116 is usually formed of the same type of a material as that of the side wall spacer 115. Thereby, the side wall spacer 115 is also easily etched during a process in which the contact hole 118 is formed by selective etching of the insulating interlayer 116. Furthermore, the source-drain region 112a is shallowly formed, and also has low-impurity concentration in an region just under the side wall spacer 115 before etching, because the source-drain regions 112a and 112b are of a lightly doped drain (LDD) structure. Thereby, the lower end of the contact plug 117 is in contact with the source-drain region 112a in one side (to the left side in FIG. 7) of regions just under the side wall spacer 115, and a circuit for a leakage current is formed.

In order to solve the above problem, Japanese Laid-open patent publication NO. 2002-33389 has disclosed a technology as described as follows.

FIG. 9 is a principal cross-sectional view showing the configuration of a semiconductor device illustrated in FIG. 2 of the Japanese Laid-open patent publication NO. 2002-33389. The structure of the MOS transistor included in the semiconductor device 101 is similar to the structure shown in FIG. 19 of the patent publication. A contact hole 118, which vertically penetrates through the insulating interlayer 116, is formed in the interior of the insulating interlayer 116. In this contact hole 118, two contact holes 118a and 118b, which are formed in the insulating interlayer 116 in close vicinity to each other, are joined with each other in the upper part. The schematic plan view of the contact hole 118 is shown in FIG. 10. That is, the contact hole 118 has a gourd-shape the width of which is broad at the both ends and narrow at the center. The inside of the contact hole 118 is filled up with the conductive contact plug 117. The lower end of the contact plug 117 is divided into two branches. One branch is in contact with the surface of the source-drain region 112a through the contact hole 118a, and the other branch is in contact with the surface of the gate electrode 114 through the contact hole 118b. As described above, the source-drain region 112a and the gate electrode 114 are electrically connected to each other through the contact plug 117 to form the local interconnection structure.

The above interconnection structure is obtained by dry etching, using a photoresist film 134 with a shape shown in FIG. 11. One example of a mask M1 used for making a pattern on the photoresist film 134 is shown in FIG. 13. As shown in FIG. 13, the mask M1 has two rectangular windows w1a and w1b. The window w1a is located just above the source-drain region 112a, and is used for forming the contact hole 118a. The window w1b is located just above the gate electrode 114, and is used for forming the contact hole 118b. The above mask M1 is used to form one window 134a, which is formed by jointing two windows w1a and w1b together, in the photoresist film 134 as shown in FIG. 11. At this time, a remaining portion 134b corresponding to a part between the windows w1a and w1b of the mask M1 remains on the insulating interlayer 116 in the window 134a.

The reason why the above remaining portion 134b remains has been described in Japanese Laid-open patent publication NO. 2002-33389 as follows: That is, with regard to the remaining portion 134b, a distance D between the widows w1a and w1b is set at about one third of the wavelength of light used for performing exposure in a photolithography process; When the distance D is set at nearly the value, the exposure of the remaining portion 134b between the windows w1a and w1b is insufficient because the distance a little larger than the resolution limit of the light used at performing exposure; and, thereby, the portion 134b is not completely removed to cause a state in which the remaining portion 134b remains on the insulating interlayer 116 as shown in FIG. 11.

When anisotropic etching of the insulating interlayer 116 is carried out, using the photoresist film 134 with a pattern shown in FIG. 11 as a mask, the insulating interlayer 116 is selectively etched as shown in FIG. 12 to form the contact hole 118a corresponding to the window w1a in the mask M1, and the contact hole 118b corresponding to the window w1b in the mask M1. At this time, a remaining portion 116a in the insulating interlayer 116 is formed between the contact holes 118a and 118b as shown in FIG. 12 by the effects of the remaining portion 134b in the photoresist film 134. Moreover, there is provided a structure in which the contact holes 118a and 118b are joined to each other in the upper portion.

When the contact plug with the divided structure is formed, the side wall spacer 115 is etched, and the leakage current is prevented from being caused.

However, it is sometimes difficult in forming a common contact with a divided structure as shown in FIG. 9 as designed, because finer elements have been developed in recent years. According to a study by the inventor, it has been found that, when the diameter of a contact is small, there is caused a shortage of light amounts at performing exposure, and the diameter of the contact becomes smaller than a designed size to cause a defective contact. The above finding will be explained, referring to FIGS. 14A to 14C

FIG. 14A is an exemplary view showing a photoresist opening pattern, wherein the pattern is used when exposure is performed by using a reticle in which the comparatively large-size contact 101 is arranged. In a location in which the distance between the contacts 101 is comparatively wide, a resist opening with a designed shape is obtained as is the case for an opening 102. On the other hand, as is the case for an opening 103, an opening with an elliptic shape, which is larger than a designed size, is formed in a location, in which the distance between the contacts 101 is comparatively narrow, because adjoining openings are united into one. The center portion of the elliptic opening is formed to be broader in width in comparison with a designed size. This kind of problem similarly comes up even in the case of a slit-like contact (a contact with a configuration in which the dimension in the longitudinal direction is longer than that of the cross direction).

FIG. 14B is a view showing a case in which the size of a contact is smaller than that of FIG. 14A. Even in this case, an elliptic opening is formed in such a way that the elliptic opening stretches over adjoining contacts 104, and the area of the opening is smaller than that of FIG. 14A. When a small-sized contact 104 is formed on a reticle, an opening 105 in a photoresist is smaller than a designed size because a shortage of light amounts is caused at performing exposure.

FIG. 14C shows an example in which the distance between adjoining contacts 104 is larger than that of the arrangement shown in FIG. 14B. In this case, a resist opening is formed in each of contacts 104 as shown in the drawing, and the size of the resist opening is further smaller than that of FIG. 14B. The reason is that a shortage of light amounts is markedly caused at performing exposure.

In order to solve the problem relating to the shortage of light amounts at performing exposure, it has been considered that a large opening is provided on a reticle beforehand. However, the above solution is not necessarily a realistic one because, in the case of the layouts shown in FIGS. 14B and 14C, ratios between the dimension of the pattern on the reticle and that of the resist opening obtained with the pattern vary greatly, depending on process factors.

As described above, the problem relating to the shortage of light amounts at performing exposure is caused when the size of the via is made finer, and measures against the above problem become important.

The present invention has been made, considering the above circumstances, and an object of the invention is to control a defective opening caused by the shortage of light amounts at performing exposure for forming a contact and a via.

### SUMMARY OF THE INVENTION

According to the present invention, there is provided a semiconductor device, including: a semiconductor substrate; a first conductor provided on the surface or in the upper portion of the semiconductor substrate; an insulating interlayer covering the first conductor; a second conductor provided on the insulating interlayer; and a conductive plug which is provided in the insulating interlayer and connects the first conductor and the second conductor, wherein the cross-sectional shape of the conductive plug in a plane parallel to the surface of the semiconductor substrate includes a plurality of first regions arranged at a predetermined distance in the longitudinal direction, and a second region joining the first regions, and the length of the second region in the longitudinal direction is equal to, or shorter than 0.5 times as long as that of the first region in the longitudinal direction.

According to the present invention, there is provided a method of manufacturing a semiconductor device, including: forming a first conductor on the surface, or in the upper portion of a semiconductor substrate; forming an insulating interlayer covering the first conductor; forming a resist film on the insulating interlayer; forming an opening in the resist film by developing after performing exposure with a predetermined reticle; etching the insulating interlayer under use of the resist film, which is formed with the opening, as a mask, and forming a connecting hole; embedding a conductive layer into the connecting hole, and forming a conductive plug; and forming a second conductor, which is connected to the conductive plug, on the conductive plug, wherein the shape of a portion corresponding to the conductive plug on the reticle includes a plurality of first portions arranged at a predetermined distance in the longitudinal direction, and a second portion which joins the first portions, and has a width narrower than that of the first portions, and the length of the second portion in the longitudinal direction is equal to, or shorter than 0.5 times as long as that of the first region in the longitudinal direction.

According to the present invention, there is provided a semiconductor device which prevents a defective opening caused by the shortage of light amounts at performing exposure for forming a contact and a via, and is excellent in productivity, because the device has a configuration in which the section shape of the first conductor has a shape including the first regions (the first portions) and the second region (the second portion) joining the first regions, and the first regions (first portions) are adjacent to each other.

According to the present invention, a defective opening caused by the shortage of light amounts at performing exposure for forming a contact or a via is effectively solved.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view schematically showing the structure of a semiconductor device according to an embodiment;

FIG. 2 is a view showing a plane shape of a contact plug;

FIGS. 3A to 3C are cross-sectional views schematically showing processes for a method of manufacturing the semiconductor device according to the embodiment;

FIGS. 4A and 4B are views showing a relation between a reticle and a photoresist opening;

FIG. 5 is a view showing a relation between the position of an opening and that of the gate electrode, and the like;

FIG. 6 is a view showing another example of the plane shape for a contact plug;

FIG. 7 is a view showing an example of a local interconnection structure using a common contact;

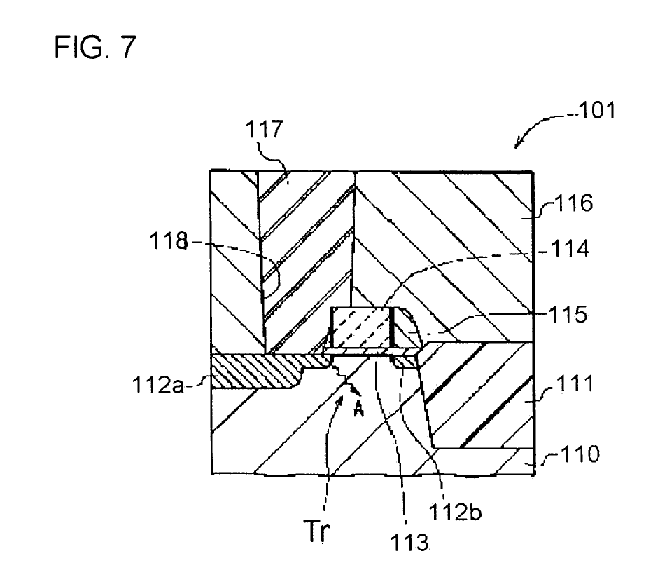

FIGS. 8A and 8B are views showing a conventional example of a mask pattern used when a contact hole is formed;

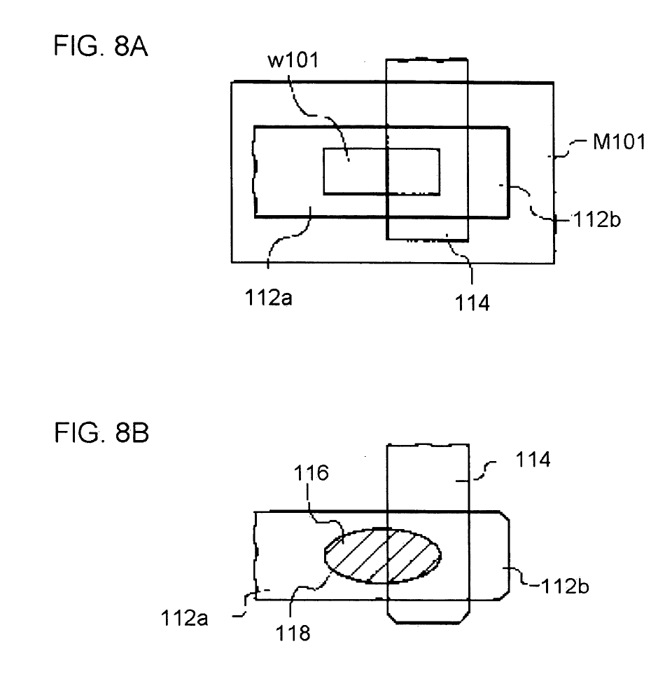

FIG. 9 is a cross-sectional view schematically showing the structure of the semiconductor device according to a conventional technology;

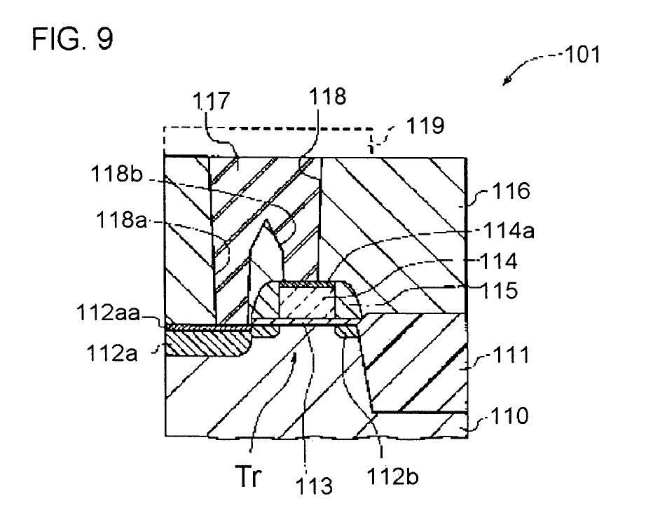

FIG. 10 is a cross-sectional view schematically showing the structure of the semiconductor device according to the conventional technology;

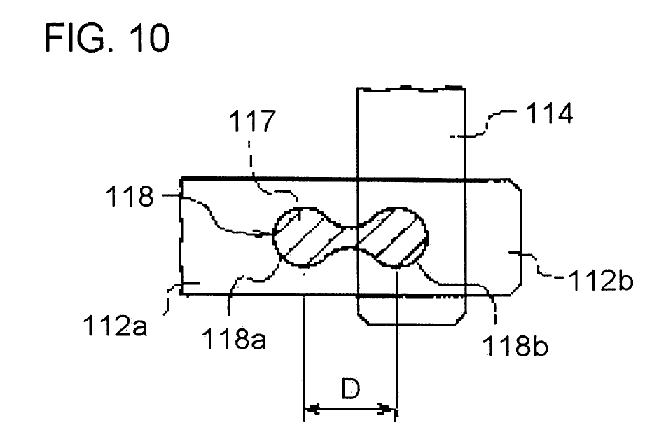

FIG. 11 is a cross-sectional view of a contact hole according to the conventional technology;

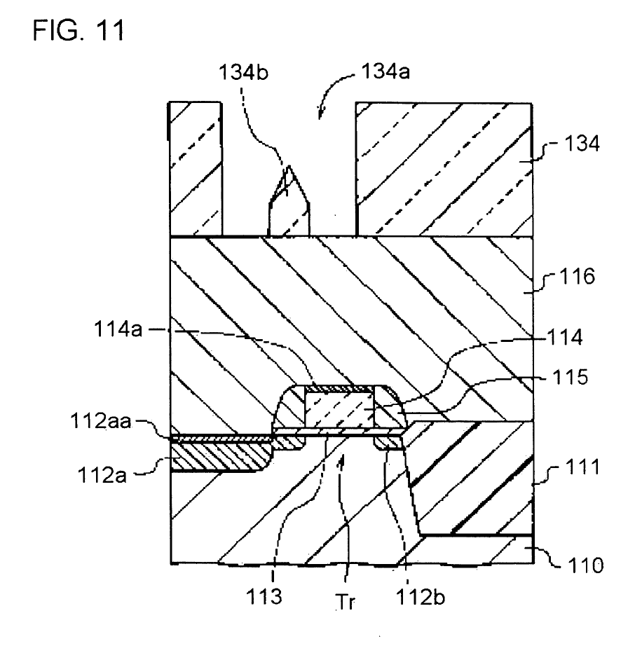

FIG. 12 is a cross-sectional view schematically showing a method of manufacturing the semiconductor device according to the conventional technology;

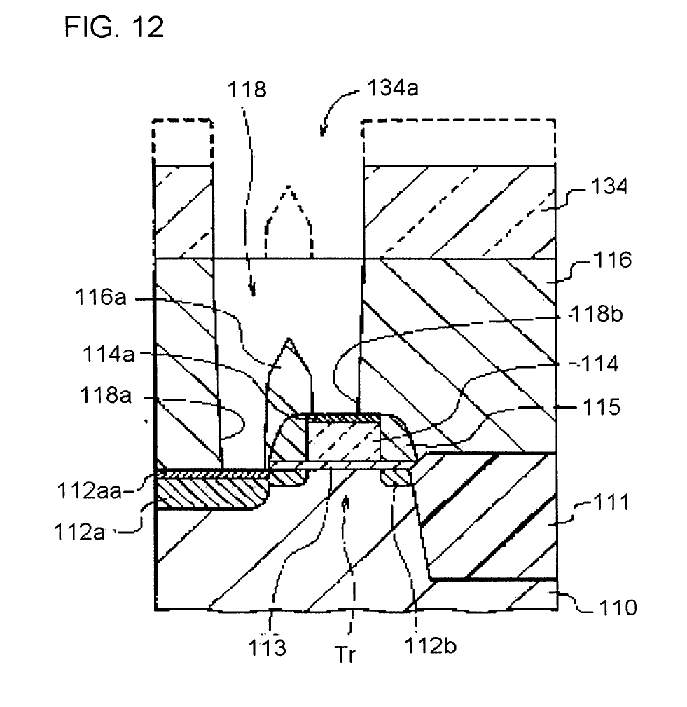

FIG. 13 is a view showing an example of a mask according to the conventional technology;

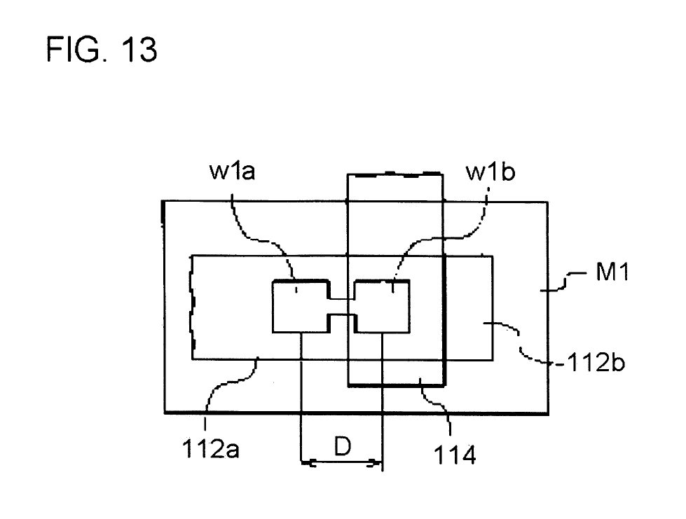

FIGS. 14A to 14C are schematic views explaining that a problem of the shortage of light amounts at performing exposure is caused in a conventional semiconductor device;

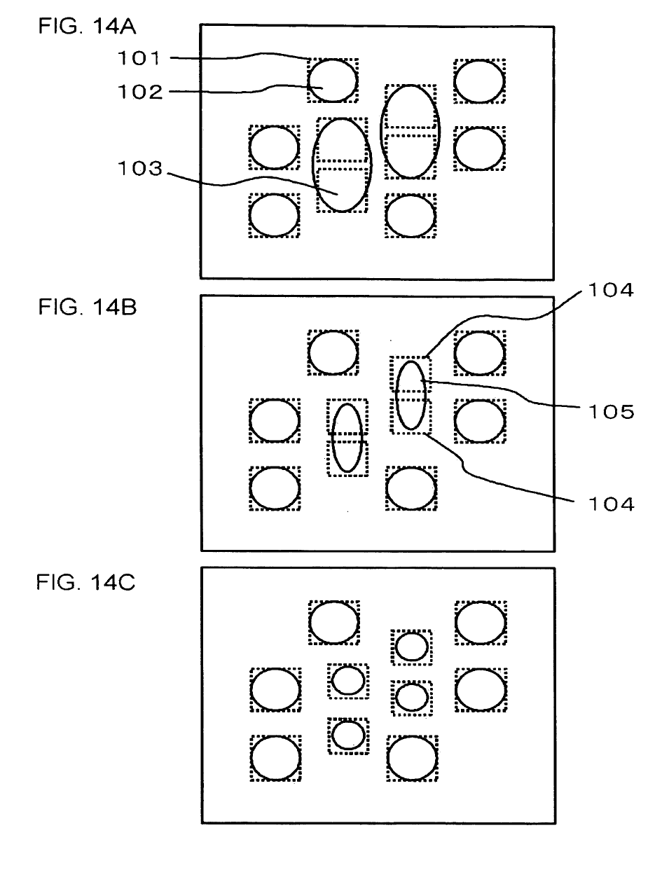

FIG. 15 is a view showing another example of a plane shape of a contact plug; and

FIG. 16 is a view showing dimensions of contact plugs which were made and evaluated in an example.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, embodiments according to the present invention will be explained, referring to drawings. Here, same components in all the drawings will be denoted by the same reference numbers, and the explanation will be properly eliminated.

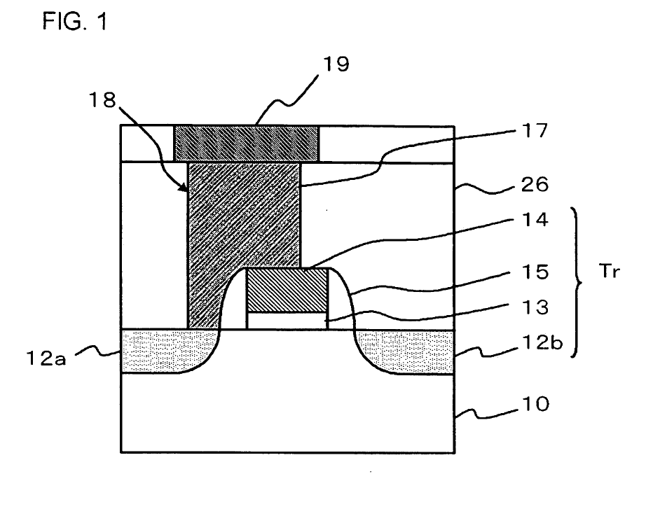

FIG. 1 is a principal cross-sectional view showing the configuration of a semiconductor device 1 according to the present embodiment.

The semiconductor device 1 includes: a MOS transistor Tr; an upper interconnection 19; and a contact plug 17 connecting the above transistor and the above interconnection, and is provided with: a silicon substrate 10; a first conductor (impurity diffusion region 12a, and a gate electrode 14) provided on the surface, or the upper portion of the silicon substrate 10; an insulating interlayer 26 covering the first conductor; a second conductor (upper interconnection 19) provided on the insulating interlayer 26; and a conductive plug (contact plug 17) which is provided in the insulating interlayer 26 and connects the first conductor and the second conductor.

The MOS transistor Tr is provided with: one couple of source-drain regions 12a and 12b which are formed near on the surface of the silicon substrate 10, and have conductivity reverse to that of the silicon substrate 10; agate insulating film 13 formed on the surface of the silicon substrate 10; a gate electrode 14 formed on the gate insulating film 13; and one couple of side walls 15 which are formed at the both sides of the gate electrode 14. A silicide region (not shown) is formed in the upper portion of the source-drain region 12a and the gate electrode 14, respectively, in order to reduce the electric resistance.

The MOS transistor Tr is covered with the insulating interlayer 16 formed on the whole surface of the silicon substrate 10. A contact hole 18, which vertically penetrates through the insulating interlayer 16, is formed in the interior of the insulating interlayer 16. The inside of the contact hole 18 is filled up with the conductive contact plug 17, and the source-drain region 12a, the gate electrode 14, and the upper interconnection 19 are electrically connected to one another through the contact plug 17. Accordingly, the local interconnection structure is formed.

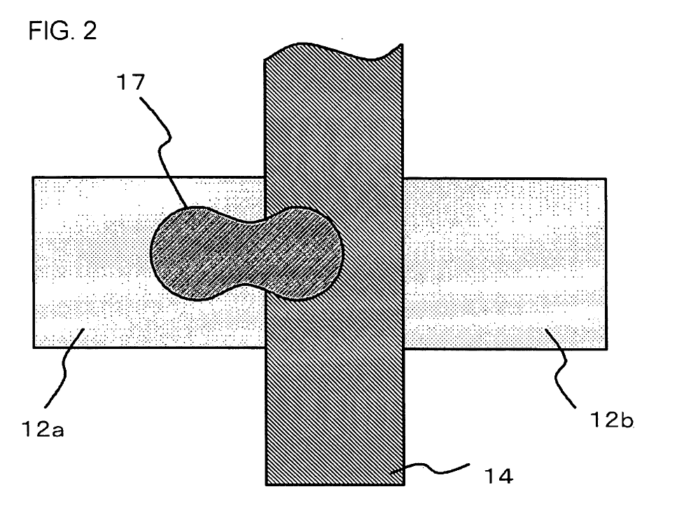

The schematic plan view of the contact hole 17 is shown in FIG. 2. That is, the hole 17 has a gourd-shape the width of which is broad at the both ends and narrow at the center.

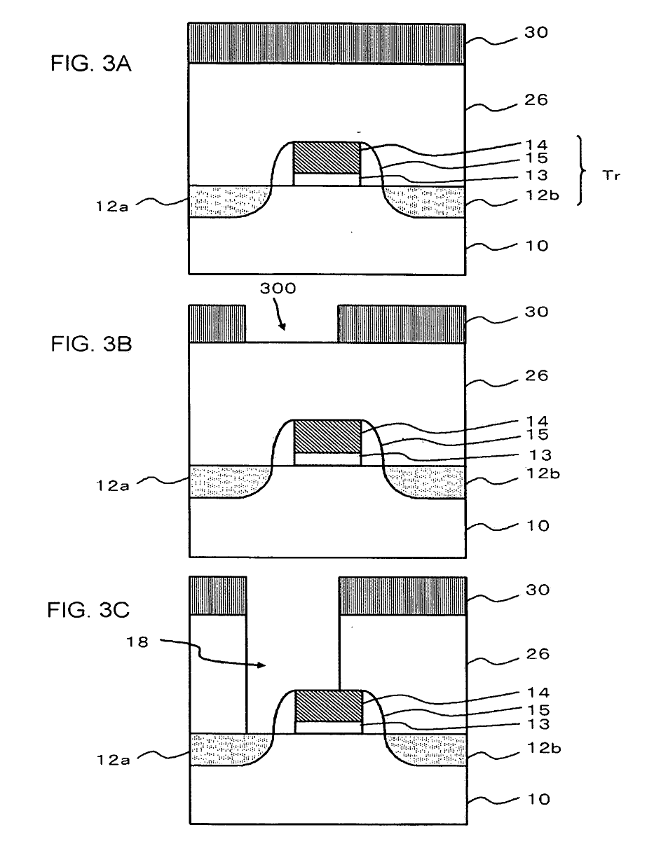

A method of manufacturing a semiconductor device shown in FIG. 1 and FIG. 2 will be explained, referring to FIG. 3A to FIG. 3C. In the first place, the gate insulating film 13, and the gate electrode 14 are formed on the silicon substrate 10. Then, the side walls 15 are formed by etch back after forming an insulating film on the whole surface of the substrate. Subsequently, ion injection onto the whole surface of the substrate is performed, the source-drain regions 12a and 12b are formed on the parts of the silicon substrate 10 around the gate electrode 14. Therefore, the insulating interlayer 26 is deposited in such a way that the interlayer 26 covers the MOS transistor Tr, and, thereafter, a photoresist 30 is deposited on the interlayer 26. As described above, a structure shown in FIG. 3A is obtained.

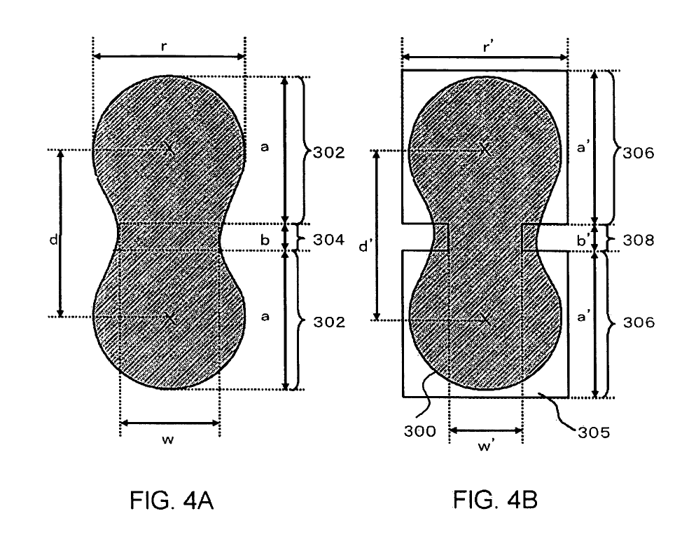

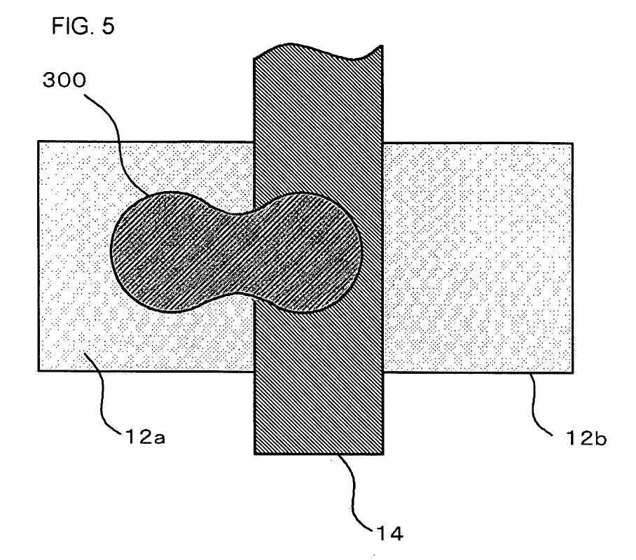

Then, the photoresist 30 is patterned to form the opening at the predetermined position. At this time, the relation between the reticle and the photoresist opening is shown in FIG. 4B (FIGS. 4A and 4B will be described later). Exposure and developing are performed, using the reticle provided with the opening pattern 305 shown in FIG. 4B, and an opening 300 is formed in the photoresist 30 as shown in FIGS. 3B and 4B. The positional relation of the opening 300 and that of the gate electrode 14, and the like is shown in FIG. 5.

The contact hole 18 shown in FIG. 3C is formed by dry etching of the insulating interlayer 26 with the resist film. A metal layer is embedded into the contact hole 18 according to the well-known damascene process, and the contact plug 17 is formed. Thereafter, an insulation film is formed on the contact plug 17, and, thereafter, and the semiconductor device shown in FIG. 1 and FIG. 2 is formed by forming the upper interconnection 19 according to the damascene process.

Then, the plane shape of the reticle pattern and that of the contact plug 17, which are used in the above-described manufacturing processes, will be explained.

FIG. 4A is a plan view of the contact plug 17. FIG. 4B shows that the contact plug 17 and the reticle pattern, which is used when the plug 17 is formed, are overlapped. This reticle pattern is the reticle pattern which is used in the exposure process when the contact hole corresponding to the contact plug 17 is formed, and, in the process shown in FIG. 3B, is used when the opening 300 is provided in the photoresist 30.

As shown in FIG. 4A, the cross-sectional shape of the contact plug 17 in a plane parallel to the surface of the semiconductor substrate includes a plurality of first regions 302 arranged at a predetermined distance in the longitudinal direction, and a second region 304 which has a width narrower than that of the first region, and joins the first regions 302 which are adjacent to each other. Each of the first regions 302 has a circular-arc shape (at least a part of the outside edge of the region has the circular-arc shape).

The present embodiment has a configuration in which a distance d between the center points of the first regions 302, and a longitudinal length b of the second regions 304 are set small. The first regions 302 have the shape of a common contact plug. In the structure of a conventional semiconductor device, the distance between the plugs is set sufficiently larger than an exposure resolution when a plurality of contact plugs are provided. For example, the longitudinal length b of the second region is set equal to, or longer than the longitudinal length a of the first region. When the plug diameter is comparatively large, and the above arrangement is adopted, a certain processing accuracy is secured, and a plug with a nearly designed shape is formed.

On the other hand, the shortage of light amounts at performing exposure is eliminated in the present embodiment by setting the distance between plugs small. Especially, the method according to the present embodiment is effective for, for example, a case in which a fine plug with a contact diameter of less than 0.2 μm is formed.

In the present embodiment, the plane shape of the contact plug is set as follows:

The longitudinal length a of the first region 302=the width (diameter) r of the first region 302

The longitudinal length b of the second region 304=d−r

b/a=(d−r)/r, and

A ratio b/a=(d−r)/r between the longitudinal length of the second region 304 and that of the first region 302 is set equal to or less than 0.5, preferably, equal to or less than 0.3.

When b/a is equal to or less than 0.5, a structure with good manufacturing stability and good yield can be realized. When b/a is equal to or less than 0.3, the manufacturing stability and the yield can be remarkably improved. The upper limit of b/a is determined to be 0.5 depending on experimental results, explained later in Example.

Further, b/a is more than 0 and preferably equal to or more than 0.1. When b/a is equal to or more than 0.1, a structure with good shape stability of a constriction (the second region 304) can be realized.

Moreover, the width of the second region 304 (diameter) w is narrower than that of the first region 302 r.

Preferably, the length b and b′ are set at a length shorter than a resolution limit at an exposure process for forming the contact plug 17. The value b and b′ are set, preferably, at a value equal to or shorter than 0.5 times, and, more preferably, at a value equal to or shorter than 0.3 times as long as the exposure wavelength at performing exposure of the reticle. Moreover, it is preferable that the value of b and b′ are less than the minimum distance between interconnections in the semiconductor device.

The minimum distance between interconnections is usually set at the resolution limit at an exposure process. The resolution limit is usually 0.5 times as long as the exposure wavelength. When b and b′ are equal to or less than the resolution limit, a phenomenon that the adjoining first regions 302 are united into one when the distance between them is narrow tends to take place more prominently. Accordingly the problem of the shortage of light amounts at performing exposure can be solved.

The cross-sectional shape of the contact plug 17 has a nearly uniform shape from the bottom to the top, and, at any sections, includes a plurality of the first regions 302, and the second regions 304 joining the first regions 302.

A reticle pattern shown in FIG. 4B is used for forming the contact plug 17 with the above-described shape. In FIG. 4B, the opening pattern 305 on the reticle corresponding to the plug includes a plurality of first portions 306 arranged in such a way that the portions 302 are separated from each other in the longitudinal direction, and second portions 308 joining the above portions 306. In FIG. 4B, a′=r′ and the first portions 306 have a square shape. The width w′ of the second portion 308 is narrower than the width r′ of the first portions 306.

The distance d′ between the center points of the first portions 306 is equal to the distance d between the center points of the first regions 302 in the contact plug 17. The longitudinal length of the first regions 302 is nearly equal to that of the first portions 306, and the longitudinal length of the second region 304 is nearly equal to that of the second portion 308.

The opening pattern 305 on the reticle shown in FIG. 4B has a shape parameter expressed by the following formula (d′−r′)/r′

and the parameter is preferably set as equal to or less than 0.5, and, more preferably, as equal to or less than 0.3.

A phenomenon that the adjoining first regions 302 are united into one due to narrow distance between them tends to take place more prominently, when b′/a′ is equal to or less than 0.5.

Accordingly the problem of the shortage of light amounts at performing exposure can be solved, and excellent manufacturing stability and good yield are obtained. An alienation between a diameter of an opening area in a reticle and a that of a plug formed by using the retile can be reduced.

The upper limit of b′/a′ is determined to be 0.5 depending on experimental results, explained later in a paragraph of Example. When b′/a′ is equal to or less than 0.3, the alienation can be stably reduced, thereby the manufacturing stability can be remarkably improved.

Further, b′/a′ is more than 0 and preferably equal to or more than 0.1. When b′/a′ is equal to or more than 0.1, a structure with good shape stability of a constriction (the second region 304) can be realized. When b′/a′ is too small, the shape of the constriction (the second region 304) may vary greatly and the shape of via plug can not be a gourd-shape, but an elliptic shape.

Here, the values of w/r, and w′/r′ are set to be at, preferably, 0.1 through 0.8, and, more preferably, 0.2 to 0.5. When the values are in the above-mentioned range, the constriction (the second region 304) portion of the via plug is formed to be properly broader in width in comparison with a designed size and the problem of the shortage of light amounts at performing exposure can be solved.

As described above, the structure of the common contact according to the present embodiment has a configuration in which there is provided the second region 304 with a narrow width, which joints the first regions 302, and, at the same time, a state in which the first regions 302 are adjacent to each other is caused by making the distance between the first regions 302 shorter. Thereby, the following advantages are obtained.

Firstly, according to the structure of the common contact of the present embodiment, the shortage of the light amounts at resist exposure is controlled at manufacturing, and excellent manufacturing stability is realized. In the present embodiment, the shape parameter (a ratio between the length of the first region and that of the second region) is expressed by the following formula
(d′−r′)/r′
and the parameter is defined as equal to or less than 0.5. Accordingly, the regions 302 are stably formed as designed. That is, the width of the first regions 302 in the mask opening is nearly equal to the width r′ of the first portions 306 on the reticle, and the amount of scatter in the values r is remarkably controlled. The reason is that the shortage of light amounts at performing exposure is effectively eliminated with a configuration in which the cross-sectional shape of the contact plug has the above-described one. When the distance between the first regions 302 is large even under a state in which the second region 304 joins the first regions 302, satisfactory effects are hardly obtained, and especially, there is a tendency that the amount of scatter in the values r is large.

Recently, the diameter of the contact hole has been made finer and finer in the semiconductor device, and there has been a tendency in which the problem of the shortage of the light amounts at performing exposure becomes more remarkable. According to the present embodiment, the above problem is effectively solved.

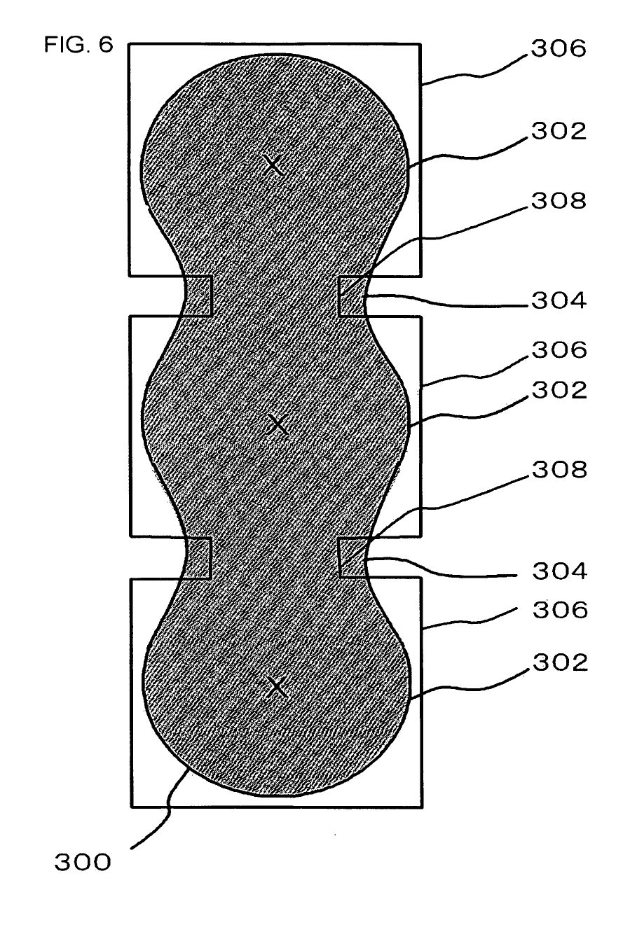

Secondly, an excellent electric characteristic with low resistance is obtained according to the structure of the common contact structure in the present embodiment. Since the common contact structure according to the present embodiment has a structure in which a plurality of the first regions 302 are joined, the cross-sectional area of the contact may be made large, a plug with low resistance may be realized. Moreover, the number of joined regions may be set as three as shown in FIG. 6, or as a number larger than three, though the number of joined regions has been set as two in the present embodiment. Further low resistance may be easily achieved with the above-described configuration.

Thirdly, according to the present embodiment, the leakage current is controlled, and a structure with high reliability is achieved. According to the structure of the common contact of the present embodiment, the disappearance of the side walls is effectively controlled because the insulating interlayer is stably etched in the process for forming the contact hole. When the slit-like contact hole which has been explained in the paragraph of “Related Art” is formed, the etching speed of the insulating interlayer is increased in comparison with that of a case in which a common round hole is formed. On the other hand, according to the common contact of the present embodiment, the etching speed of the insulating interlayer is nearly equal to that of a case in which an usual round hole is formed, and the amount of scatter in the etching speed is suppressed to low level, because the common contact has the cross-sectional shape with a constriction (the second region 304) as described above. In addition, the present embodiment adopts an arrangement in which the constriction (the second region 304) is located just above the side walls 15, and the opening area of the resist on the side wall 15 is set small in the process for forming the contact hole. From the above points, the disappearance of the side walls 15 is effectively controlled in this embodiment.

Though the embodiment according to the present invention has been described, referring to the drawings, as described above, the present embodiment is illustrative, and various kinds of configurations other than the above-described ones may be adopted.

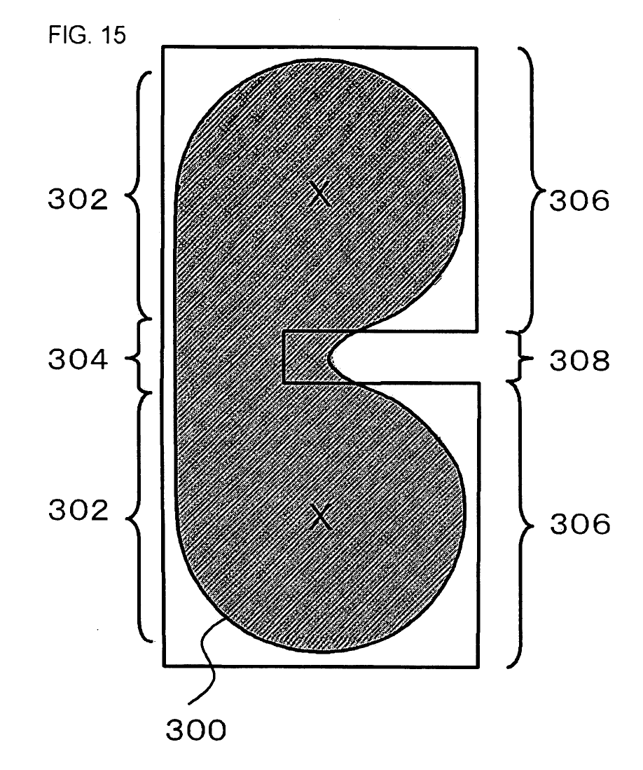

For example, the above-described embodiment has a configuration in which the centers of the first portions 306 and that of the second portion 308 are arranged to lie on the same straight line in the longitudinal direction as shown in FIG. 4B, and, similarly, the centers of the first regions 302 and that of the second region 304 are arranged to lie on the same straight line in the longitudinal direction as shown in FIG. 4A. However, the present invention is not limited to the above embodiment. The above centers are not necessarily required to be on the same straight line, and, for example, may have a shape shown in FIG. 15.

Moreover, the present invention may be applied to a via plug, which connects an upper and a lower interconnections of a multilayer interconnection, and the like, though the example in the contact plug which connects the transistor and the interconnection has been explained in this embodiment. Even in this case, similar effects to the above-described ones are obtained. That is, the problem of the shortage of light amounts at performing exposure is solved, and excellent manufacturing stability is obtained. Moreover, damages of the lower interconnection as a base in the etching process when a via plug is formed is controlled, and a via plug with low resistance and less leak is obtained.

### EXAMPLE 1

A semiconductor device with a common contact plug of a structure shown in FIG. 1 and FIG. 2 in the embodiment was formed, and the manufacturing stability was evaluated. The semiconductor device includes a transistor having a gate electrode provided on said semiconductor substrate, an impurity diffusion region provided on the surface of the semiconductor substrate around said gate electrode and a common contact plug which is connected to both of the gate electrode and the impurity diffusion region.

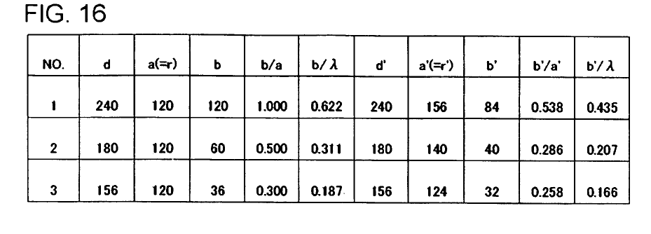

Plugs with various kinds of cross-sectional shapes were formed by changing the reticle pattern and varying the shape of the resist opening as shown in FIG. 16, and the dimension stability was evaluated. In FIG. 16, a, a′, b, b′, d, d′, r and r′ are defined in a similar manner to those of FIGS. 4A and 4B, and are expressed in nanometers.

The a, b, d, and r are the parameter about planar configuration of the obtained contact plug (FIG. 4A).

a: a longitudinal length of the first region 302

b: a longitudinal length of the second region 304

d: a distance between the center points of the first regions 302

r: a width (diameter) of the first region 302

a=r

b/a=(d−r)/r

On the other hand, the a′, b′, d′, and r′ are the parameter about reticle pattern for forming the contact plug (FIG. 4B).

a′: a longitudinal length of the first region 302

b′: a longitudinal length of the second region 304

d′: a distance between the center points of the first regions 302

r′: a width (diameter) of the first region 302

a′=r′

b′/a′=(d′−r′)/r′

In any cases, the following relations were set: r=a, and r′=a′, that is, the first regions and the first portions were configured to have a square shape.

The common contact plug was made according to the method which has been explained in the embodiment. The manufacturing conditions in a process for patterning a mask which was used for forming a contact hole were as follows.

Exposure wavelength: 193 nanometers (ArF),

Resolution: nearly 120 nanometers, and

Minimum distance between the interconnections of the semiconductor device: 120 nanometers

In the present example, the diameter of the plug for the first region (the length a of the first region) was set as 120 μm in any cases. On the other hand, the length b of the second region in the longitudinal direction was changed (samples NO. 1 through NO. 3), and the manufacturing stability of the plug was evaluated. The manufacturing stability was evaluated, based on an alienation r/r′ of the cross-sectional shape of a plug from a designed value. The r/r′ means a dimension alienation between obtained plug and designed one. The value of r/r′ close to 1 shows that the plug has been formed as designed. The small value of r/r′ shows that the obtained plug has been formed smaller than a designed size due to the shortage of light amounts at performing exposure.

A NO. 1 sample has b/a and b′/a′ values which are more than 0.5. On the other hand, NO. 2 and 3 samples have b/a and b′/a′ values which are equal to or less than 0.5. It is found as shown in FIG. 16 that the alienation between r and r′ (r/r′=0.77) was large in a NO. 1 case, the alienation between r and r′ (r/r′=0.86) was small in a NO. 2 case, and the alienation between r and r′ (r/r′=0.97) was small in a NO. 3 case. Moreover, it is confirmed that the amount of scatter for the ratios r/r′ which have been obtained at evaluating a plurality of the samples was larger in the NO. 1 case in comparison with those of the NO. 2 and NO. 3 cases. According to the structures of NO. 2 and NO. 3, the designed dimension of the resist opening can be obtained. When b/a and b′/a′ are equal to or less than 0.5 as shown in a NO. 2 case and a NO. 3 case, the plug can be formed as designed.

It is found from the above description that the shape stability of the plug was improved with a plane shape including two first regions which were joined to each other through the second region, and with the reduced distance (b in FIG. 4A) between the first regions. The reason is considered that the shortage of light amounts at performing exposure is eliminated by the above configuration.

It is apparent that the present invention is not limited to the above embodiment, that may be modified and changed without departing from the scope and spirit of the invention.

What is claimed is:

1. A semiconductor device, comprising:
a semiconductor substrate;
a first conductor provided on the surface or in the upper portion of said semiconductor;
an insulating interlayer covering said first conductor;
a second conductor provided on said insulating interlayer; and
a conductive plug which is provided in said insulating interlayer and connects said first conductor and said second conductor,
wherein the cross-sectional shape of said conductive plug in a plane parallel to the surface of said semiconductor substrate includes a plurality of first regions arranged at a predetermined distance in the longitudinal direction, and a second region joining said first regions, and the length of said second region in the longitudinal direction is equal to, or shorter than 0.5 times as long as that of said first region in the longitudinal direction.

2. The semiconductor device according to claim 1,
wherein the length of said second region in the longitudinal direction is equal to, or shorter than 0.5 times as long as that of said first region in the longitudinal direction.

3. The semiconductor device according to claim 1,
wherein each of said first regions has a circular-arc shape;
assuming that the diameter of said first region is r, a distance between the center points of said first regions is d, the length of said first region in the longitudinal direction is r, and the length of said second region is expressed by (d−r); and
the length (d−r) of said second region in the longitudinal direction is equal to, or shorter than 0.5 times as long as that of said first region in the longitudinal direction.

4. The semiconductor device according to claim 3,
wherein the length (d−r) of said second region in the longitudinal direction is equal to, or shorter than 0.5 times as long as that of said first region in the longitudinal direction.

5. The semiconductor device according to claim 1,
wherein said second region has a width narrower than that of said first region.

6. The semiconductor device according to claim 1,
wherein the length of said second region in the longitudinal direction is shorter than the minimum distance between interconnections in said semiconductor device.

7. The semiconductor device according to claim 1,
wherein the length of said second region in the longitudinal direction is equal to or shorter than 0.5 times as long as an exposure wavelength in a process for patterning a photoresist used for forming said conductive plug.

8. The semiconductor device according to claim 1,
wherein the cross-sectional shape of said conductive plug has a nearly uniform shape from the bottom to the top of said conductive plug.

9. The semiconductor device according to claim 1, comprising:
a transistor including a gate electrode provided on said semiconductor substrate; and an impurity diffusion region provided on the surface of said semiconductor substrate around said gate electrode,
wherein said first conductor includes said gate electrode and said impurity diffusion region, and
said conductive plug is a common contact plug which is connected to both of said gate electrode and said impurity diffusion region.

10. A method of manufacturing a semiconductor device, comprising:
forming a first conductor on the surface, or in the upper portion of a semiconductor substrate;
forming an insulating interlayer covering said first conductor;
forming a resist film on said insulating interlayer;
forming an opening in said resist film by developing after performing exposure with a predetermined reticle;
etching said insulating interlayer under use of said resist film, which is formed with said opening, as a mask, and forming a connecting hole;
embedding a conductive layer into said connecting hole, and forming a conductive plug; and
forming a second conductor, which is connected to said conductive plug, on said conductive plug,
wherein the shape of a portion corresponding to said conductive plug on said reticle includes a plurality of first portions arranged at a predetermined distance in the longitudinal direction, and a second portion which joins said first portions, and has a width narrower than that of said first portions, and the length of said second portion in the longitudinal direction is equal to, or shorter than 0.5 times as long as that of said first region in the longitudinal direction.

11. The method of manufacturing a semiconductor device according to claim 10,
wherein the length of said second portion in the longitudinal direction is equal to, or shorter than 0.5 times as long as that of said first region in the longitudinal direction.

12. The method of manufacturing a semiconductor device according to claim 10,
wherein each of said first portions has a circular-arc shape;
assuming that the diameter of said first portions is r′, and a distance between the center points of said first portions is d′, the length of said first portion in the longitudinal direction is r′, and the length of said second portion is expressed by (d′−r′); and
the length (d′−r′) of said second portion in the longitudinal direction is equal to, or shorter than 0.5 times as long as that of said first portion in the longitudinal direction.

13. The method of manufacturing a semiconductor device according to claim 12,
wherein the length (d′−r′) of said second portion in the longitudinal direction is equal to, or shorter than 0.5 times as long as that of said first portion in the longitudinal direction.

14. The method of manufacturing a semiconductor device according to claim 10,
wherein said distance between the center points of said first portions is equal to, or shorter than 0.5 times as long as an exposure wavelength at performing exposure of said reticle.

15. The method of manufacturing a semiconductor device according to claim 10,
the length of said second portion in the longitudinal direction is shorter than the minimum distance between interconnections in said semiconductor device.

16. The method of manufacturing a semiconductor device according to claim 10,
wherein said connecting hole is formed in such a way that the shape of said hole has a nearly uniform shape from the bottom to the top of said hole.

17. The method of manufacturing a semiconductor device according to claim 10,
wherein forming said first conductor forms a gate electrode on said semiconductor substrate, and, at the same time, includes forming an impurity diffusion region on the surface of said semiconductor substrate around said gate electrode;
said first conductor comprises said gate electrode and said impurity diffusion region; and
said connecting hole is formed in such a way that said hole is in communication with both of said gate electrode and said impurity diffusion region.
